(19) United States
(12) Patent Application Publication
(10) Pub. No.: US 2026/0128257 A1
(43) Pub. Date: May 7, 2026

(54) PLASMA PROCESSING APPARATUS

(71) Applicant: Tokyo Electron Limited, Tokyo (JP)

(72) Inventor: Masaki HIRAYAMA, Tokyo (JP)

(21) Appl. No.: 19/438,924

(22) Filed: Jan. 2, 2026

Related U.S. Application Data
(63) Continuation of application No. PCT/JP2024/023004, filed on Jun. 25, 2024.

(30) Foreign Application Priority Data
Jul. 7, 2023 (JP) 2023-112344

(51) Int. Cl. H01J 37/32; H01P 7/04

(52) U.S. Cl. CPC H01J 37/32082; H01P 7/04

(57) ABSTRACT

A plasma processing apparatus includes: a chamber; a substrate support provided in the chamber; an excitation electrode provided above the substrate support; an emitter configured to emit electromagnetic waves to a plasma generation space below the excitation electrode; and a resonator provided above the excitation electrode, wherein the resonator includes first and second ends and a plurality of slots, wherein the plurality of slots are arranged in a circumferential direction along the second end, and wherein a length of each of the plurality of slots in a longitudinal direction, which is the circumferential direction, is changeable.

### CROSS-REFERENCE TO RELATED APPLICATION

The application is a Bypass Continuation Application of PCT International Application No. PCT/JP 2024/023004, filed on Jun. 25, 2024 and designating the United States, the international application being based upon and claiming the benefit of priority from Japanese Patent Application No. 2023-112344, filed on Jul. 7, 2023, the entire contents of which are incorporated herein by reference.

### TECHNICAL FIELD

The present disclosure relates to a plasma processing apparatus.

### BACKGROUND

Plasma processing apparatuses are used in processing substrates. As a type of plasma processing apparatuses, a known apparatus excites a gas using radio-frequency waves such as very high frequency (VHF) waves or ultra high frequency (UHF) waves. A plasma processing apparatus disclosed in Patent Document 1 includes a processing container, a stage, an upper electrode, an introduction part, and a waveguide part. The stage is provided in the processing container. The upper electrode is provided above the stage via a space in the processing container. The introduction part is an introduction part for radio-frequency waves. The introduction part is provided at a lateral end portion of the space and extends circumferentially around a central axis of the processing container. The waveguide part is configured to supply the radio-frequency waves to the introduction part. The waveguide part includes a resonator configured to provide a waveguide. The waveguide of the resonator extends circumferentially around the central axis, extends in an extension direction of the central axis, and is connected to the introduction part.

### PRIOR ART DOCUMENT

### Patent Document

Patent Document 1: Japanese Patent Application Publication No. 2020-92031.

### SUMMARY

One embodiment of the present disclosure provides a plasma processing apparatus. The plasma processing apparatus includes a chamber, a substrate support, an excitation electrode, an emitter, and a resonator. The chamber provides a processing space in the chamber. The substrate support is provided in the chamber. The excitation electrode has a central axis and is provided above the substrate support. The emitter is configured to emit electromagnetic waves to a plasma generation space below the excitation electrode. The emitter extends in a circumferential direction with respect to the central axis to surround the plasma generation space. The resonator is provided above the excitation electrode. The resonator includes first and second ends configured to resonate the electromagnetic waves between the first end and the second end, and a plurality of slots configured to supply the electromagnetic waves from the plurality of slots to the emitter. The plurality of slots are arranged in the circumferential direction along the second end. A longitudinal direction of each of the plurality of slots is the circumferential direction, and a length of each of the plurality of slots in the longitudinal direction is changeable.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a plasma processing apparatus according to an exemplary embodiment.

FIG. 2 is a cross-sectional view taken along line II-II in FIG. 1.

FIG. 3 is a view showing a plasma processing apparatus according to another exemplary embodiment.

FIG. 4 is a cross-sectional view taken along line IV-IV in FIG. 3.

FIG. 5 is a cross-sectional view taken along line V-V in FIG. 3.

FIG. 6 is a cross-sectional view taken along line VI-VI in FIG. 3.

FIG. 7 is a view showing an example of a positional relationship between a plurality of first slots and a plurality of second slots.

FIG. 8 is a view showing another example of the positional relationship between the plurality of first slots and the plurality of second slots.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Various exemplary embodiments will be described in detail below with reference to the drawings, in which the same or equivalent parts are designated by the same reference numerals.

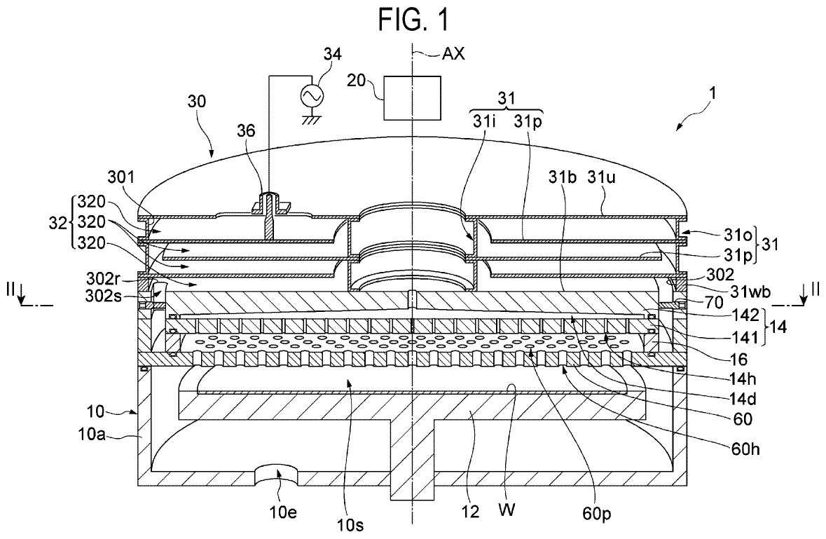

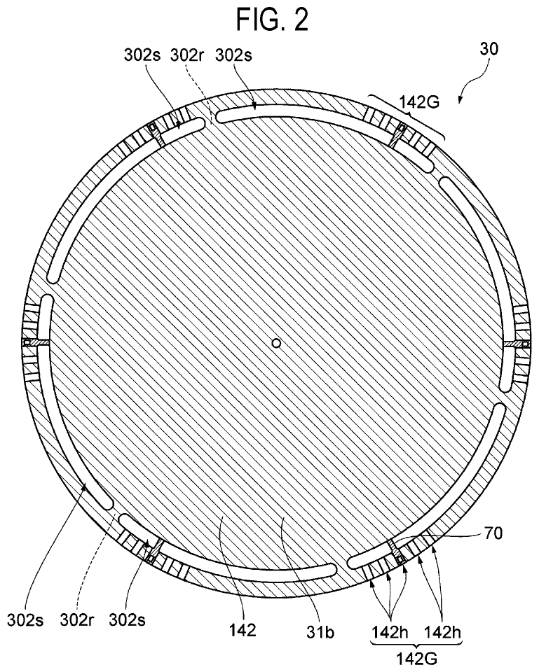

FIG. 1 is a view showing a plasma processing apparatus according to an exemplary embodiment. FIG. 2 is a cross-sectional view taken along line II-II in FIG. 1. The plasma processing apparatus 1 shown in FIGS. 1 and 2 includes a chamber 10, a substrate support 12, an excitation electrode 14, an emitter 16, and a resonator 30.

The chamber 10 provides a processing space 10s therein. In the plasma processing apparatus 1, a substrate W is processed in the processing space 10s. The chamber 10 is made of a metal such as aluminum and is grounded. The chamber 10 has a sidewall 10a and has an open upper end. The chamber 10 and the sidewall 10a may have a substantially cylindrical shape. The processing space 10s is provided inward of the sidewall 10a. A central axis of each of the chamber 10, the sidewall 10a, and the processing space 10s is an axis AX. The chamber 10 may have a corrosion-resistant film on a surface thereof. The corrosion-resistant film may be an yttrium oxide film, an yttrium oxide fluoride film, an yttrium fluoride film, or a ceramic film containing yttrium oxide or yttrium fluoride.

A bottom portion of the chamber 10 provides an exhaust port 10e. An exhaust device is connected to the exhaust port 10e. The exhaust device may include a vacuum pump such as a dry pump and/or a turbomolecular pump, and an automatic pressure control valve.

The substrate support 12 is provided in the processing space 10s. The substrate support 12 is configured to support the substrate W placed horizontally on an upper surface of the substrate support 12. The substrate support 12 has a substantially disk-like shape. A central axis of the substrate support 12 is the axis AX.

The excitation electrode 14 is provided above the substrate support 12 via the processing space 10s. The excitation electrode 14 is made of a conductive material such as metal (e.g., aluminum) and has a substantially disk-like shape. A central axis of the excitation electrode 14 is the axis AX.

The plasma processing apparatus 1 further includes an electrode 60. The electrode 60 is another excitation electrode. The electrode 60 has a substantially disk-like shape and is disposed to close the opening at the upper end of the chamber 10. The electrode 60 has a plurality of holes 60h. The plurality of holes 60h penetrate the electrode 60 in a thickness direction. The excitation electrode 14 is disposed above the electrode 60. The excitation electrode 14 and the electrode 60 define a plasma generation space 60p therebetween. In the plasma processing apparatus 1, the plasma generation space 60p is spaced apart from the processing space 10s and provided above the processing space 10s.

The emitter 16 is provided to emit electromagnetic waves therefrom into the plasma generation space. In the plasma processing apparatus 1, the emitter 16 surrounds the plasma generation space 60p and is sandwiched between the excitation electrode 14 and the electrode 60. The electromagnetic waves emitted from the emitter 16 into the plasma generation space may be radio-frequency waves such as VHF waves or UHF waves. The emitter 16 is made of a dielectric material such as quartz, aluminum nitride, or aluminum oxide. The emitter 16 extends circumferentially around the axis AX. The emitter 16 may have a ring shape.

In one embodiment, the excitation electrode 14 may include a shower plate 141 and an upper electrode 142. The shower plate 141 is provided above the plasma generation space 60p. The shower plate 141 provides a plurality of gas holes 14h. The plurality of gas holes 14h extend in a thickness direction (vertical direction) of the shower plate 141 and penetrate the shower plate 141.

The upper electrode 142 is provided on the shower plate 141. The upper electrode 142 forms a gas diffusion chamber 14d between the shower plate 141 and the upper electrode 142. A gas supply 20 is connected to the gas diffusion chamber 14d. Gases from the gas supply 20 pass through the gas diffusion chamber 14d and are discharged from the plurality of gas holes 14h into the plasma generation space 60p.

In the plasma processing apparatus 1, a gas in the plasma generation space 60p is excited by the electromagnetic waves emitted into the plasma generation space 60p from the emitter 16. As a result, plasma is generated in the plasma generation space 60p. Active species in the plasma generated in the plasma generation space 60p are supplied to the processing space 10s via the plurality of holes 60h.

The resonator 30 is provided on the excitation electrode 14. The resonator 30 is electromagnetically coupled to the emitter 16. The resonator 30 provides a waveguide 32. The resonator 30 includes a conductor 31 that partitions and defines the waveguide 32. The conductor 31 is made of a conductive material such as a metal. The conductive material forming the conductor 31 may include aluminum, stainless steel, copper, brass, or the like.

The resonator 30 includes a first end 301 and a second end 302. The first end 301 is one end of the waveguide 32, and the second end 302 is the other end of the waveguide 32. The resonator 30 is configured to reflect the electromagnetic waves propagating in the waveguide 32 at the first end 301 and the second end 302 and resonate the electromagnetic waves. The electromagnetic waves resonating in the resonator 30 are supplied to the emitter 16 from a plurality of slots 302s (described later) and emitted into the plasma generation space.

The plasma processing apparatus 1 may further include a radio-frequency power supply 34. The radio-frequency power supply 34 is configured to generate radio-frequency power. The electromagnetic waves introduced into the plasma generation space are generated based on the radio-frequency power generated by the radio-frequency power supply 34. The radio-frequency power supply 34 may be directly connected to the resonator 30 by using a coaxial line. That is, the radio-frequency power supply 34 may be coupled to the waveguide of the resonator 30 without a matcher for impedance matching. A coaxial line may include a connector 36 as a connection portion to the resonator 30. The connector 36 may be connected to the resonator 30 so as to introduce the electromagnetic waves into the resonator 30 from an uppermost layer of a plurality of layers 320 (described below) of the waveguide 32. In this case, an inner conductor of the connector 36 is connected to a conductor plate 31p (described below) that partitions and defines the uppermost layer from below, and an outer conductor of the connector 36 is connected to a conductor plate 31p (upper wall 31u) that partitions and defines the uppermost layer from above.

In one embodiment, the waveguide 32 may have a folded structure including a plurality of folded portions. In one embodiment, the waveguide 32 may be configured to be axially symmetric or rotationally symmetric with respect to the axis AX. Further, in one embodiment, the conductor 31 may include an inner portion 31i (or inner peripheral portion), an outer portion 31o (or outer peripheral portion), and the plurality of conductor plates 31p.

The plurality of conductor plates 31p extend radially with respect to the axis AX and are arranged parallel to one another in the vertical direction, which is a direction in which the axis AX extends. The inner portion 31i and the outer portion 31o extend coaxially with respect to the axis AX. Each of the inner portion 31i and the outer portion 31o may have a substantially cylindrical shape having a central axis of the axis AX. Each of the inner portion 31i and the outer portion 31o may be formed as a tubular (e.g., cylindrical) conductor wall extending between the conductor plates 31p adjacent in the vertical direction.

The waveguide 32 may also include the plurality of layers 320. The plurality of layers 320 extend radially with respect to the axis AX between the inner portion 31i and the outer portion 31o, and are arranged alternately with the plurality of conductor plates 31p. Each of the plurality of layers 320 is connected to a layer directly thereabove among the plurality of layers 320 at one of the plurality of folded portions along the inner portion 31i or the outer portion 31o.

In one embodiment, the first end 301 is provided above the second end 302. The first end 301 is provided by the outer portion 31o of the resonator 30. The first end 301 surrounds the uppermost layer among the plurality of layers 320.

The second end 302 is formed by a wall 31wb of the outer portion 31o that surrounds a bottommost layer among the plurality of layers 320. The second end 302 is disposed above the emitter 16 and extends in a circumferential direction around the axis AX. As shown in FIG. 2, a plurality of slots 302s are formed in a bottom conductor plate 31b, which partitions and defines a bottommost layer among the plurality of conductor plates 31p from below. In the plasma processing apparatus 1, the conductor plate 31b also serves as the upper electrode 142. The plurality of slots 302s are arranged in a vicinity of or along the second end 302. The plurality of slots 302s are coupled to the emitter 16 at a location outward of the excitation electrode 14. The plurality of slots 302s extend in a circumferential direction with respect to the axis AX and are arranged along the circumferential direction. The plurality of slots 302s are arranged alternately with the plurality of portions 302r in the conductor plate 31b. In one embodiment, a radial distance between the axis AX and an outer edge of each of the plurality of slots 302s may be approximately the same as a radius of the wall 31wb of the outer portion 31o. In the resonator 30, the electromagnetic waves are reflected at the second end 302 toward the first end 301. In addition, a portion of the electromagnetic waves propagating in the resonator 30 is coupled to the emitter 16 via the plurality of slots 302s.

As shown in FIG. 2, each of the plurality of slots 302s extends in a longitudinal direction which is the circumferential direction, and a length of each of the plurality of slots 302s in the longitudinal direction can be changed.

As shown in FIGS. 1 and 2, in the plasma processing apparatus 1, the resonator 30 further includes a plurality of short-circuiting members 70. Each of the plurality of short-circuiting members 70 short-circuits a pair of edges of a corresponding one of the plurality of slots 302s extending in the circumferential direction. As a result, each of the plurality of short-circuiting members 70 changes the length of the corresponding slot in the longitudinal direction.

In one embodiment, each of the plurality of short-circuiting members 70 may be a screw (e.g., a set screw) made of a metal. In this case, a plurality of screw hole groups 142G are formed in the resonator 30, specifically, in the conductor plate 31b (or the upper electrode 142). Each of the plurality of screw hole groups 142G includes a plurality of screw holes 142h. Each of the plurality of screw holes 142h in each of the plurality of screw hole groups 142G extends radially with respect to the axis AX. The plurality of screw holes 142h in each of the plurality of screw hole groups 142G penetrate one of the pair of edges of a corresponding slot among the plurality of slots 302s, and are arranged in the circumferential direction along that edge. The plurality of screw holes 142h in each of the plurality of screw hole groups 142G may be provided between one end and a center of the corresponding slot in the longitudinal direction and penetrate one edge of the corresponding slot.

In one embodiment, the plurality of screw holes 142h in each of the plurality of screw hole groups 142G penetrate the conductor plate 31b from an outer edge of the conductor plate 31b to the corresponding slot. Each of the plurality of short-circuiting members 70, i.e., the screw, short-circuits a pair of edges of the corresponding slot via a selected one of the plurality of screw holes 142h that penetrate one edge of the corresponding slot and the corresponding slot.

In the plasma processing apparatus 1, the length of the plurality of slots 302s in the longitudinal direction is adjusted by the plurality of short-circuiting members 70. As the length of the plurality of slots 302s is reduced, a Q value of the resonator 30 is increased. Therefore, according to the plasma processing apparatus 1, the Q value of the resonator 30 can be adjusted.

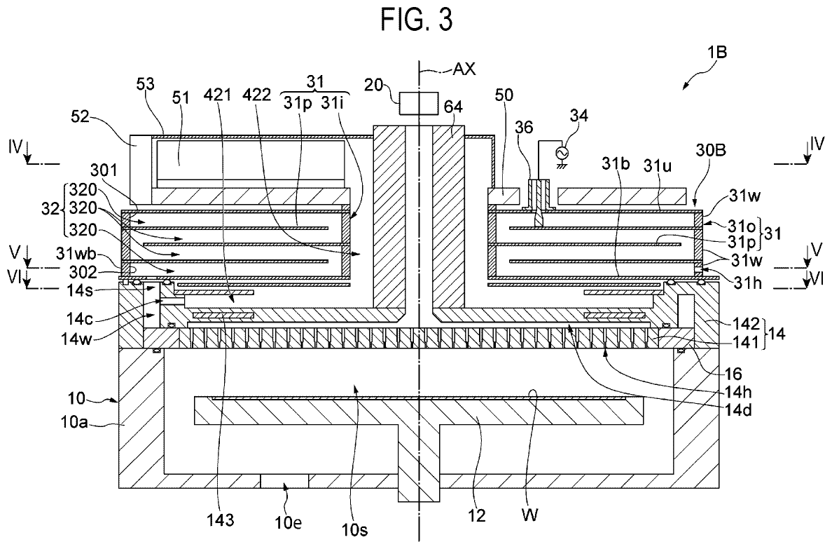

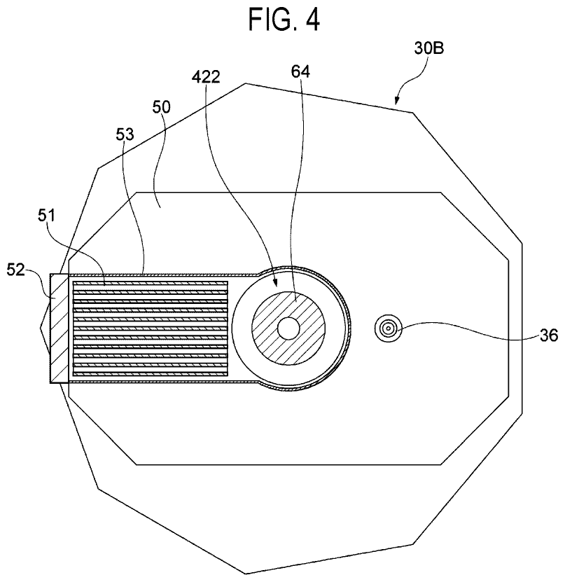

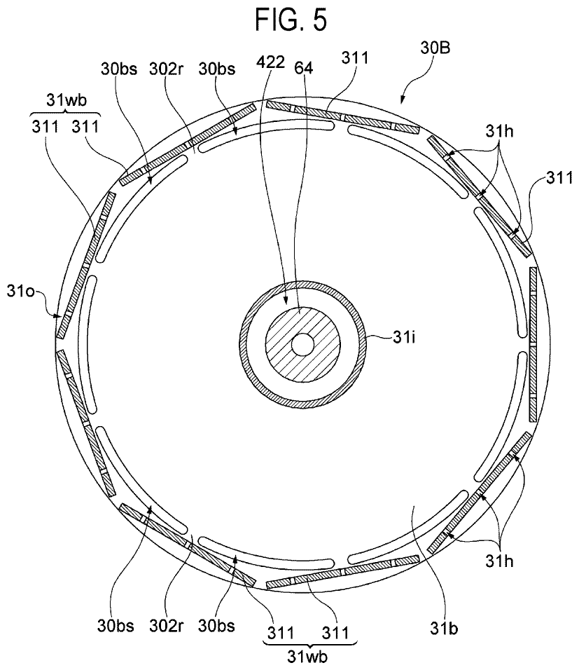

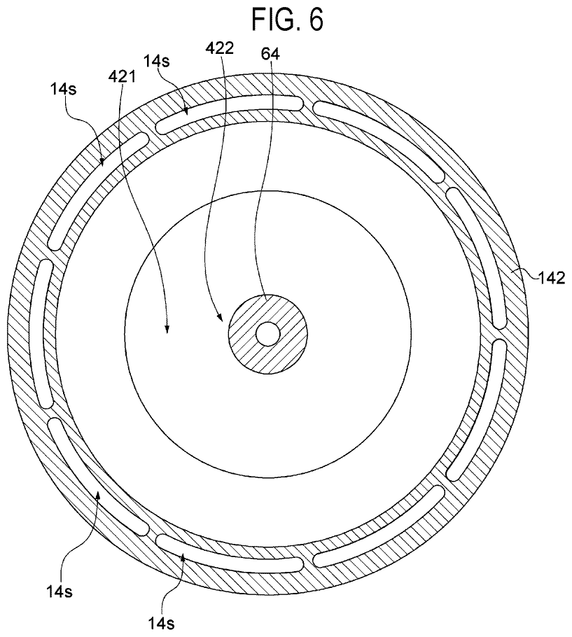

A plasma processing apparatus according to another exemplary embodiment will be described below with reference to FIGS. 3 to 6. FIG. 3 is a view showing a plasma processing apparatus according to another exemplary embodiment. FIG. 4 is a cross-sectional view taken along line IV-IV in FIG. 3. FIG. 5 is a cross-sectional view taken along line V-V in FIG. 3. FIG. 6 is a cross-sectional view taken along line VI-VI in FIG. 3. A plasma processing apparatus 1B shown in FIGS. 3 to 6 will be described below from a viewpoint of differences from the plasma processing apparatus 1.

The plasma processing apparatus 1B does not include the electrode 60. In the plasma processing apparatus 1B, the emitter 16 extends to surround the shower plate 141. The shower plate 141 and the emitter 16 close the opening at the upper end of the chamber 10. In the plasma processing apparatus 1B, a plasma generation space is a space directly below the shower plate 141 in the processing space 10s.

The plasma processing apparatus 1B may further include a gas pipe 64. The gas pipe 64 is disposed inward of the inner portion 31i and extends in the vertical direction. A central axis of the gas pipe 64 is located on the axis AX. The gas pipe 64 is connected between the gas diffusion chamber 14d and the gas supply 20.

The plasma processing apparatus 1B includes a resonator 30B instead of the resonator 30. The resonator 30B will be described below from a viewpoint of differences from the resonator 30. In the resonator 30B, the conductor plate 31b is a conductor plate different from the upper electrode 142 and extends above the upper electrode 142. Further, a plurality of slots 302s are provided by the conductor plate 31b and the upper electrode 142.

Specifically, as shown in FIG. 5, a plurality of slots 30bs (a plurality of first slots) are formed in the conductor plate 31b (a first conductor plate). The plurality of slots 30bs have the circumferential direction with respect to the axis AX as a longitudinal direction thereof. The plurality of slots 30bs are arranged at equal intervals along the circumferential direction. Further, as shown in FIG. 6, a plurality of slots 14s (a plurality of second slots) are formed in the upper electrode 142 (a second conductor plate). The plurality of slots 14s have the circumferential direction with respect to the axis AX as a longitudinal direction thereof. The plurality of slots 14s are arranged at equal intervals along the circumferential direction. The plurality of slots 14s are disposed below the plurality of slots 30bs.

The number of the slots 14s is the same as the number of the slots 30bs. A radius of curvature of inner edges of the slots 14s about the axis AX is the same as or substantially the same as a radius of curvature of inner edges of the slots 30bs about the axis AX. A radius of curvature of outer edges of the slots 14s about the axis AX is the same as or substantially the same as a radius of curvature of outer edges of the slots 30bs about the axis AX. Further, a length of the slots 14s in the longitudinal direction is the same as or substantially the same as a length of the slots 30bs in the longitudinal direction.

In the resonator 30B, each of the plurality of slots 302s is formed as one of the plurality of slots 30bs and one of the plurality of slots 14s, which overlap with each other in the vertical direction. In the resonator 30B, the conductor plate 31b and the upper electrode 142 are configured so that a length of each of the plurality of slots 302s can be changed by adjusting a positional relationship between the plurality of slots 30bs and the plurality of slots 14s in the circumferential direction. Therefore, one or both of the conductor plate 31b and the upper electrode 142 are configured to be rotatable around the axis AX. That is, the plurality of slots 30bs and/or the plurality of slots 14s can be rotated in the circumferential direction around the axis AX. One or both of the conductor plate 31b and the upper electrode 142 may be rotated manually. Alternatively, one or both of the conductor plate 31b and the upper electrode 142 may be rotated by an actuator such as a motor or the like and a controller that controls the actuator.

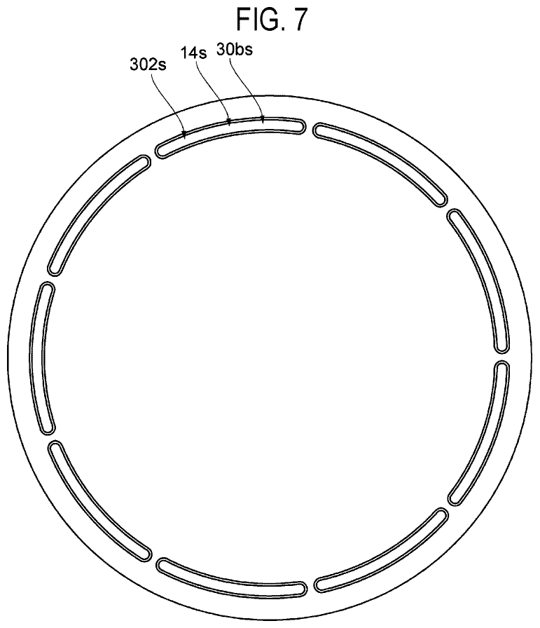

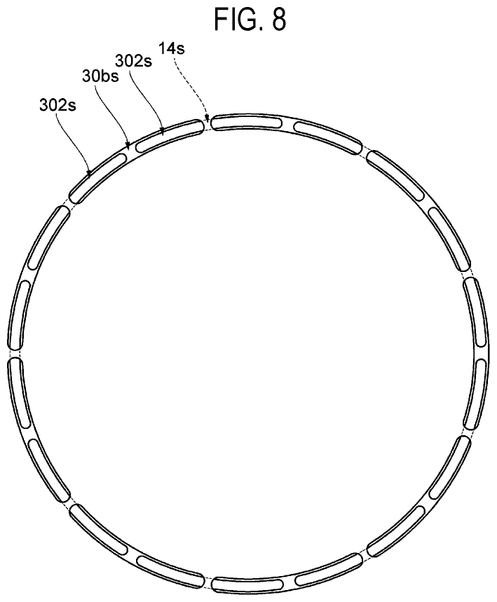

Now, reference will be made to FIGS. 7 and 8. FIG. 7 is a view showing an example of a positional relationship between the plurality of first slots and the plurality of second slots. FIG. 8 is a view showing another example of the positional relationship between the plurality of first slots and the plurality of second slots. As shown in FIG. 7, each of the plurality of slots 302s in the circumferential direction has a maximum value when center positions of the plurality of slots 30bs in the circumferential direction and center positions of the plurality of slots 14s in the circumferential direction coincide with each other. On the other hand, as shown in FIG. 8, the length of each of the plurality of slots 302s in the circumferential direction is reduced when the center positions of the plurality of slots 30bs in the circumferential direction and the center positions of the plurality of slots 14s in the circumferential direction are offset from each other.

In the plasma processing apparatus 1B, it is possible to adjust the lengths of the plurality of slots 302s in the circumferential direction, i.e., longitudinal direction, as described above. Therefore, according to the plasma processing apparatus 1B, it is possible to adjust a Q value of the resonator 30B.

Hereinafter, reference will be made to FIGS. 3 to 6 again together with FIGS. 7 and 8. The number of slots 302s in the resonator 30B is nine in a state shown in FIG. 7. That is, the number of slots 302s is an odd number. When the number of slots 302s is an odd number, generation of an electric field intensity distribution (or plasma density distribution), which is two-fold rotationally symmetric about the axis AX, in the plasma generation space is suppressed, compared to a case where the number of slots 302s is an even number. The number of slots 302s may be any odd number other than nine, as long as it is five or more. Further, the number of slots 302s in the resonator 30B may also be an even number.

In the plasma processing apparatus 1B, the outer portion 31o has a generally cylindrical shape and has the axis AX as its central axis. The outer portion 31o may include a plurality of walls 31w. Each of the plurality of walls 31w extends between corresponding conductor plates 31p adjacent to each other in the vertical direction and has a generally cylindrical shape. Among the plurality of walls 31w, at least the wall 31wb surrounding the bottommost layer extends along sides of a polygon in a cross section perpendicular to the axis AX. Two or more or all of the plurality of walls 31w may extend along the sides of a polygon in a cross section perpendicular to the axis AX. In one embodiment, the wall 31wb may have a polygonal tube shape. Further, two or more or all of the plurality of walls 31w may have a polygonal tube shape. Further, in the example shown in the figures, the polygon is a regular nonagon, but may be another polygon.

In one embodiment, the wall 31wb may be formed as a plurality of plate-like bodies 311. Further, each of two or more or all of the plurality of walls 31w may be formed as a plurality of plate-like bodies 311. Each of the plurality of plate-like bodies 311 is made of the above-mentioned metal. Each of the plurality of plate-like bodies 311 may be a flat plate. Each of the plurality of plate-like bodies 311 extends along a corresponding side of the above-mentioned polygon in a cross section perpendicular to the axis AX.

In the resonator 30B, a magnitude of a current flowing radially in the conductor plate 31b with respect to the axis AX has a circumferential distribution in which the magnitude of the current is minimized in directions from the axis AX toward corners of the polygon and maximized in directions from the axis AX toward centers of each side of the polygon. Therefore, in each of the plurality of slots 302s, the electric field intensity distribution in the circumferential direction is adjusted.

In one embodiment, the number of slots 302s in the state shown in FIG. 7 may be the same as the number of corners of the polygon. Further, when the slots 302s are in the state shown in FIG. 7, a position of each corner of the polygon and a center position of a corresponding slot 302s in the circumferential direction may be aligned radially with respect to the axis AX. Typically, the magnitude of the current flowing radially in the conductor plate 31b is maximized in a direction toward the center of each slot 302s. However, in the resonator 30B, the magnitude of the current flowing radially in the conductor plate 31b has a circumferential distribution in which the magnitude of the current can be weakened at the center of each slot 302s and can be strengthened between adjacent slots 302s. Accordingly, uniformity in the circumferential distribution of electric field intensity in each of the plurality of slots 302s is increased.

As shown in FIG. 5, the plate-like bodies 311 may be spaced apart from one another to provide gaps at the corners of the polygon. Alternatively, a vertically extending edge of each of the plate-like bodies 311 may be connected to a vertically extending edge of a corresponding other plate-like body among the plurality of plate-like bodies 311 at a corresponding corner of the polygon. When the plate-like bodies 311 are spaced apart from one another to provide gaps at the corners of the polygon, the magnitude of the current flowing radially toward the corners of the polygon is further reduced.

The resonator 30B also has a plurality of inlets 31h, which connect the waveguide 32 to the outside of the resonator 30B, in any of the walls 31w of the outer portion 31o. The inlets 31h may be arranged along the circumferential direction. In one embodiment, the plurality of inlets 31h are provided in the wall 31wb and connects the bottommost layer among the plurality of layers 320 of the waveguide 32 to the outside of the resonator 30B.

In the plasma processing apparatus 1B, the excitation electrode 14 (e.g., the upper electrode 142) may include a heating mechanism 143 embedded therein. The heating mechanism 143 may be a heater such as a resistance heating element. In this case, the heating mechanism 143 is connected to a heater power source. Power of the heater power source may be controlled by a controller according to a difference between a temperature of the excitation electrode 14 measured by a temperature sensor and a target value.

The upper electrode 142 provides a waveguide 14w between each of the plurality of slots 302s and the emitter 16. The waveguide 14w extends in the circumferential direction around the axis AX and has a ring shape in a plan view. In the plasma processing apparatus 1B, the electromagnetic waves emitted from the plurality of slots 302s are supplied to the emitter 16 via the waveguide 14w.

In addition, the upper electrode 142 provides a cavity 421 at a location inward of the waveguide 14w and between the upper electrode 142 and the resonator 30B. The cavity 421 is connected to the waveguide 14w via a plurality of communication holes 14c. The communication holes 14c are arranged in the circumferential direction. In the plasma processing apparatus 1B, the cavity 421 is connected to an external space of the resonator 30B via the plurality of inlets 31h, the waveguide 32, the plurality of slots 302s, the waveguide 14w, and the plurality of communication holes 14c.

The plasma processing apparatus 1B further includes a heat sink 51 and a fan 52. The heat sink 51 is provided above the resonator 30B and disposed on a support body 50. The fan 52 is supported by the support body 50 and connected to a flow path in the heat sink 51. In the plasma processing apparatus 1B, a cavity 422 is provided between the inner portion 31i of the resonator 30B and the gas pipe 64. The cavity 422 is connected between the cavity 421 and the flow path in the heat sink 51. The cavity 422 and the heat sink 51 are covered by a cover 53.

In the plasma processing apparatus 1B, a gas (e.g., air) outside the resonator 30B is supplied to the cavity 421 via the plurality of inlets 31h, the waveguide 32, the plurality of slots 302s, the waveguide 14w, and the plurality of communication holes 14c. The gas supplied to the cavity 421 flows along an upper surface of the upper electrode 142 and exchanges heat with the upper electrode 142, i.e., the excitation electrode 14. Thereafter, the gas passes through the cavity 422 and is supplied to the flow path in the heat sink 51. The gas is cooled in the heat sink 51 and then discharged to the outside by the fan 52.

According to the present disclosure in some embodiments, it is possible to adjust a Q value of a resonator in a plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber configured to provide a processing space in the chamber;
a substrate support provided in the processing space;
an excitation electrode having a central axis and provided above the substrate support;
an emitter configured to emit electromagnetic waves to a plasma generation space below the excitation electrode, and extending in a circumferential direction with respect to the central axis to surround the plasma generation space; and
a resonator provided above the excitation electrode,
wherein the resonator includes first and second ends configured to resonate the electromagnetic waves between the first end and the second end, and a plurality of slots configured to supply the electromagnetic waves from the plurality of slots to the emitter,
wherein the plurality of slots are arranged in the circumferential direction along the second end, and
wherein a longitudinal direction of each of the plurality of slots is the circumferential direction, and a length of each of the plurality of slots in the longitudinal direction is changeable.

2. The plasma processing apparatus of claim 1, wherein the resonator further includes a plurality of short-circuiting members, and
wherein each of the short-circuiting members is configured to change the length of a corresponding slot among the plurality of slots by short-circuiting a pair of edges of the corresponding slot extending in the circumferential direction.

3. The plasma processing apparatus of claim 2, wherein the resonator further includes a plurality of screw hole groups, each of which has a plurality of screw holes,
wherein the plurality of screw holes in each of the plurality of screw hole groups penetrate one of the pair of edges of a corresponding slot among the plurality of slots, and are arranged in the circumferential direction along the corresponding slot, and
wherein each of the plurality of short-circuiting members is a screw, and is configured to short-circuit the pair of edges via the corresponding slot and a selected one of the plurality of screw holes that penetrate the one of the pair of edges of the corresponding slot.

4. The plasma processing apparatus of claim 3, wherein the plurality of screw holes in each of the plurality of screw hole groups penetrate the one of the pair of edges at locations between an end of the corresponding slot in the longitudinal direction and a center of the corresponding slot in the longitudinal direction.

5. The plasma processing apparatus of claim 1, wherein the resonator further includes:
a first conductor plate, a longitudinal direction of which is the circumferential direction, and in which a plurality of first slots arranged along the circumferential direction are formed; and
a second conductor plate, a longitudinal direction of which is the circumferential direction, and in which a plurality of second slots arranged along the circumferential direction are formed, the second conductor plate being disposed below the first conductor plate,
wherein each of the plurality of slots is formed as one of the plurality of first slots and one of the plurality of second slots, and
wherein the first conductor plate and the second conductor plate are configured to change the length of each of the plurality of slots by adjusting a positional relationship between the plurality of first slots and the plurality of second slots in the circumferential direction.

6. The plasma processing apparatus of claim 5, wherein at least one of the first conductor plate or the second conductor plate is configured to be rotatable in the circumferential direction.

7. The plasma processing apparatus of claim 1, wherein the resonator further includes:
inner and outer portions extending coaxially with respect to the central axis; and
a plurality of conductor plates arranged parallel to one another along a vertical direction, which is a direction in which the central axis extends,
wherein the resonator provides a waveguide, which extends between the outer portion and the inner portion and includes a plurality of layers arranged alternately with the plurality of conductor plates,
wherein each of the plurality of layers is connected to a layer, which is one among the plurality of layers disposed directly above the each of the plurality of layers, at one of a plurality of folded portions arranged along the inner portion or the outer portion,
wherein the first end extends to surround an uppermost layer among the plurality of layers, and
wherein the second end extends to surround a bottommost layer among the plurality of layers.
